(19) United States
(12) Patent Application Publication
(10) Pub. No.: US 2025/0361175 A1
(43) Pub. Date: Nov. 27, 2025

(54) METHOD FOR MANUFACTURING WINDOW AND ELECTRONIC APPARATUS INCLUDING THE SAME WINDOW

(71) Applicant: Samsung Display Co., LTD., Yongin-si (KR)

(72) Inventors: BYOUNGYUL SHIM, Yongin-si (KR); HYUNCHUL KIM, Yongin-si (KR); KANG DUK CHOI, Yongin-si (KR); SEUNGPYO HONG, Yongin-si (KR)

(21) Appl. No.: 19/069,863

(22) Filed: Mar. 4, 2025

(30) Foreign Application Priority Data
May 24, 2024 (KR) 10-2024-0068018

(51) Int. Cl. C03C 15/00; H05K 5/03

(52) U.S. Cl. CPC C03C 15/00; H05K 5/03

(57) ABSTRACT

A method for manufacturing a window includes providing a glass substrate having a first non-folding area, a second non-folding area, and a folding area between the first and second non-folding areas, providing, on the glass substrate, a first bar and a second bar each of which is inclined with respect to an upper surface of the glass substrate, and spaced apart from the glass substrate, and etching the glass substrate by providing an etching solution to the upper surface of the glass substrate. In the etching the glass substrate, a recessed portion is formed in the folding area.

This application claims priority to Korean Patent Application No. 10-2024-0068018, filed on May 24, 2024, and all the benefits accruing therefrom under 35 U.S.C. § 119, the content of which in its entirety is herein incorporated by reference.

### BACKGROUND

### (1) Field

The disclosure herein relates to a method for manufacturing a window and electronic apparatus including the same window, and more particularly, to a method for manufacturing a window for a foldable electronic apparatus.

### (2) Description of the Related Art

Display devices include a display region which is activated in response to an electrical signal. The display devices may sense an input applied from the outside through the display region, and at the same time, may provide information to a user by displaying various images.

### SUMMARY

Recently, as display devices with various shapes are being developed, research is being actively conducted particularly on foldable display devices, and a method for effectively etching an ultra-thin glass (UTG) is increasingly demanded to achieve foldable properties.

Embodiments of the disclosure provide a window in which impact resistance and a defective exterior are improved.

An embodiment of the invention provides a method for manufacturing a window including providing a glass substrate including a first non-folding area, a second non-folding area, and a folding area between the first and second non-folding areas, providing, on the glass substrate, a first bar and a second bar each of which is inclined with respect to an upper surface of the glass substrate, and spaced apart from the glass substrate, and etching the glass substrate by providing an etching solution to the upper surface of the glass substrate, where in the etching the glass substrate, a recessed portion is formed in the folding area.

In an embodiment, the recessed portion may include a first inclined portion adjacent to the first non-folding area, a second inclined portion adjacent to the second non-folding area, and a third flat portion between the first and second inclined portions, and in the etching the glass substrate, a portion, of the first inclined portion, adjacent to a boundary between the first non-folding area and the folding area, and a portion, of the second inclined portion, adjacent to a boundary between the second non-folding area and the folding area may each be formed to be curved.

In an embodiment, the etching solution may be directly provided to the glass substrate.

In an embodiment, in the etching the glass substrate, the etching solution provided to the first non-folding area may flow and move along the upper surface of the glass substrate in a direction from the first non-folding area toward the folding area, and the etching solution provided to the second non-folding area may flow and move along the upper surface of glass substrate in a direction from the second non-folding area toward the folding area.

In an embodiment, in the etching the glass substrate, an etch rate of the folding area may be greater than an etch rate of each of the first non-folding area and the second non-folding area.

In an embodiment, the etching the glass substrate may include providing a nozzle part to overlap the folding area, the first non-folding area, and the second non-folding area, and spraying the etching solution onto the glass substrate through the nozzle part.

In an embodiment, in the providing the first bar and the second bar, the first bar and the second bar may respectively overlap the first non-folding area and the second non-folding area, the first bar may be disposed to be inclined in a way such that one end of the first bar, which is adjacent to the glass substrate, gets closer to an inner of the folding area, and the second bar may be disposed to be inclined in a way such that one end of the second bar, which is adjacent to the glass substrate, gets closer to an inner of the folding area.

In an embodiment, the etching solution, which is provided to the first non-folding area through the nozzle part, may flow and move along the upper surface of the glass substrate in a direction from the first non-folding area toward the folding area, and the etching solution, which is provided to the second non-folding area through the nozzle part, may flow and move along the upper surface of the glass substrate in a direction from the second non-folding area toward the folding area.

In an embodiment, the nozzle part may include a first nozzle part disposed overlapping the first non-folding area, a second nozzle part disposed overlapping the second non-folding area, and a third nozzle part disposed overlapping the folding area, and a concentration of the etching solution sprayed from the third nozzle part may be higher than a concentration of the etching solution sprayed from the first nozzle part and a concentration of the etching solution sprayed from the second nozzle part.

In an embodiment, the nozzle part may include a first nozzle part disposed overlapping the first non-folding area, a second nozzle part disposed overlapping the second non-folding area, and a third nozzle part disposed overlapping the folding area, and a temperature of the etching solution sprayed from the third nozzle part may be higher than a temperature of the etching solution sprayed from the first nozzle part and a temperature of the etching solution sprayed from the second nozzle part.

In an embodiment, the nozzle part may include a first nozzle part disposed overlapping the first non-folding area, a second nozzle part disposed overlapping the second non-folding area, and a third nozzle part disposed overlapping the folding area, and a flow direction of the etching solution may be adjusted by controlling an angle of each of the first nozzle part and the second nozzle part.

In an embodiment, the etching the glass substrate may include immersing the glass substrate in a first etching solution, providing a nozzle part to overlap the folding area, and spraying a second etching solution onto the folding area through the nozzle part.

In an embodiment, in the providing the first bar and the second bar, each of the first bar and the second bar may overlap the folding area of the glass substrate, the first bar may be disposed to be inclined in a way such that one end of the first bar adjacent to the glass substrate gets closer to an inner of the first non-folding area, and the second bar may be disposed to be inclined in a way such that one end of the second bar adjacent to the glass substrate gets closer to an inner of the second non-folding area.

In an embodiment, the nozzle part may not be provided to the first non-folding area and the second non-folding area of the glass substrate, and the second etching solution may not be sprayed thereto.

In an embodiment, a concentration of the second etching solution sprayed onto the folding area may be higher than a concentration of the first etching solution.

In an embodiment, in the providing the first bar and the second bar, a spaced distance from the first bar to the glass substrate may be the same as a spaced distance from the second bar to the glass substrate.

In an embodiment, in the providing the first bar and the second bar, an angle between the first bar and the upper surface of the glass substrate may be the same as an angle between the second bar and the upper surface of the glass substrate.

In an embodiment of the invention, a method for manufacturing a window includes providing a glass substrate under a first bar and a second bar, and etching the glass substrate by providing an etching solution to an entire upper surface of the glass substrate, where in the providing the glass substrate, each of the first bar and the second bar is inclined with respect to the upper surface of the glass substrate, and in the etching the glass substrate, a first flat portion, a second flat portion, and a recessed portion between the first and second flat portions are formed in the glass substrate.

In an embodiment, the recessed portion may include a first inclined portion adjacent to a first non-folding area, a second inclined portion adjacent to a second non-folding area, and a third flat portion between the first and second inclined portions, and in the etching of the glass substrate, a portion, of the first inclined portion, adjacent to a boundary between the first non-folding area and a folding area and a portion, of the second inclined portion, adjacent to a boundary between the second non-folding area and the folding area may each be formed to be curved.

In an embodiment, a flow direction of the etching solution may be controlled by controlling at least one selected from a spaced distance between the first bar and the glass substrate, a spaced distance between the second bar and the glass substrate, an angle between the first bar and the upper surface of the glass substrate, and an angle between the second bar and the upper surface of the glass substrate.

An embodiment of the invention provides an electronic device including a window manufactured by a method including providing a glass substrate including a first non-folding area, a second non-folding area, and a folding area between the first and second non-folding areas, providing, on the glass substrate, a first bar and a second bar each of which is inclined with respect to an upper surface of the glass substrate, and spaced apart from the glass substrate, and etching the glass substrate by providing an etching solution to the upper surface of the glass substrate, where in the etching the glass substrate, a recessed portion is formed inside the folding area.

### BRIEF DESCRIPTION OF THE DRAWINGS

The accompanying drawings are included to provide a further understanding of embodiments of the invention, and are incorporated in and constitute a part of this specification. The drawings illustrate embodiments of the invention and, together with the description, serve to explain principles of the invention. In the drawings:

FIG. 1A is an assembled perspective view illustrating an unfolded state of a display device according to an embodiment of the invention;

FIG. 1B is an assembled perspective view illustrating an in-folded state of a display device according to an embodiment of the invention;

FIG. 2 is an exploded perspective view of a display device according to an embodiment of the invention;

FIG. 3 is a cross-sectional view of a window according to an embodiment of the invention;

FIGS. 4A and 4B are cross-sectional views schematically illustrating processes of a method for manufacturing a window according to an embodiment of the invention;

FIGS. 5A to 5C are cross-sectional views schematically illustrating processes of a method for manufacturing a window according to an embodiment of the invention; and

FIG. 6 is a cross-sectional view schematically illustrating a process of a method for manufacturing a window according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In this specification, it will be understood that when an element (or region, layer, portion, etc.) is referred to as being “connected to” or “coupled to” another element, it can be directly disposed on/connected to/coupled to the other element or intervening elements may be present.

Like reference numerals or symbols refer to like elements throughout the specification. In addition, in terms of drawings, the thickness and the ratio and the dimension of the element are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

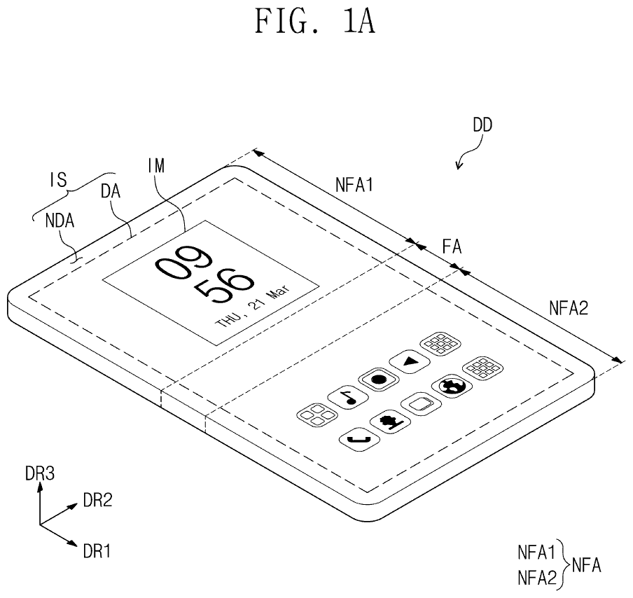

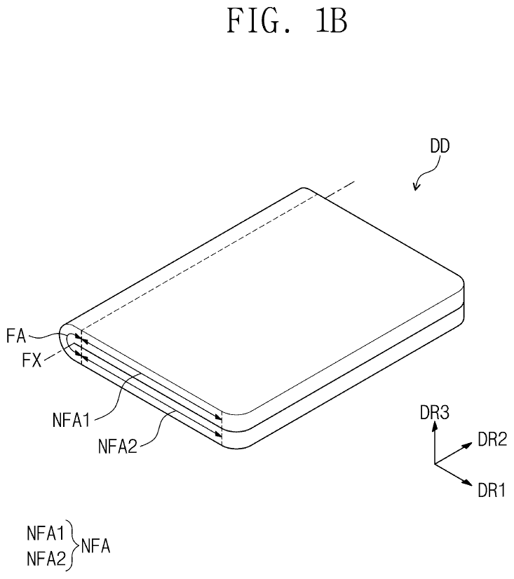

FIGS. 1A and 1B are perspective views of a display device DD according to an embodiment of the invention. FIG. 1A illustrates the display device DD in an unfolded state, and FIG. 1B illustrates the display device DD in a folded state.

Referring to FIGS. 1A and 1B, the display device DD according to an embodiment of the invention may include a display surface IS on a plane defined by a first direction DR1 and a second direction DR2 crossing the first direction DR1. The display device DD may provide an image IM to a user through the display surface IS. In the disclosure, a display device DD may mean any electronic device or apparatus including a display surface IS.

Hereinafter, a direction substantially perpendicularly crossing a plane defined by the first direction DR1 and the second direction DR2 is defined as a third direction DR3. The third direction DR3 may be a thickness direction of the display device DD. The third direction DR3 may be a basis that distinguishes between a front surface and a rear surface of each member. In this specification, the wording “on a plane” may be defined as a “state viewed in the third direction DR3”. Hereinafter, the first to third directions DR1, DR2, and DR3 may be the directions respectively indicated by first to third direction axes, and may thus be denoted as the same reference numerals or symbols.

FIGS. 1A and 1B illustrate a foldable display device as an example of the flexible display device DD. However, according to another embodiment of the invention, the display device may be a bendable display device or a rollable display device that is rolled up, and is not particularly limited. The flexible display device DD according to an embodiment of the invention may be used in a small- and medium-sized electronic apparatus such as a mobile phone, a tablet computer, a car navigation system, a game console, or a smart watch as well as in a large-sized electronic apparatus such as a television or a monitor. Hereinafter, for convenience of description, embodiment where the display device DD a foldable display device will be mainly described as an example.

In an embodiment, as illustrated in FIG. 1A, the display surface IS of the display device DD may include a plurality of regions. The display device DD may include a display region DA in which the image IM is displayed and a non-display region NDA adjacent to the display region DA. The non-display region NDA is a region in which the image is not displayed. FIG. 1A illustrates a clock widget as one example of the image IM. In an embodiment, for example, the display region DA may have a quadrangular shape in a plan view. The non-display region NDA may surround the display region DA. However, an embodiment of the invention is not limited thereto, and a shape of the display region DA and a shape of the non-display region NDA may be designed relatively. In an embodiment, the non-display region NDA may be omitted.

The display device DD may include a folding area FA and a plurality of non-folding areas NFA. The non-folding areas NFA may include a first non-folding area NFA1 and a second non-folding area NFA2. In the second direction DR2, the folding area FA may be disposed between the first non-folding area NFA1 and the second non-folding area NFA2.

In an embodiment, as illustrated in FIG. 1B, the folding area FA may be folded on the basis of a folding axis FX that is parallel to the second direction DR2. The display device DD may be in-folded so that the display surface IS is not exposed to the outside, while the first non-folding area NFA1 and the second non-folding area NFA2 are facing each other.

In an embodiment where the display device DD includes two non-folding areas NFA, the non-folding areas NFA may have a same area as each other, but an embodiment of the invention is not limited thereto. The areas of the non-folding areas NFA may be greater than an area of the folding area FA. In an embodiment, the area of the folding area FA may not be fixed, and may be determined depending on a radius of curvature.

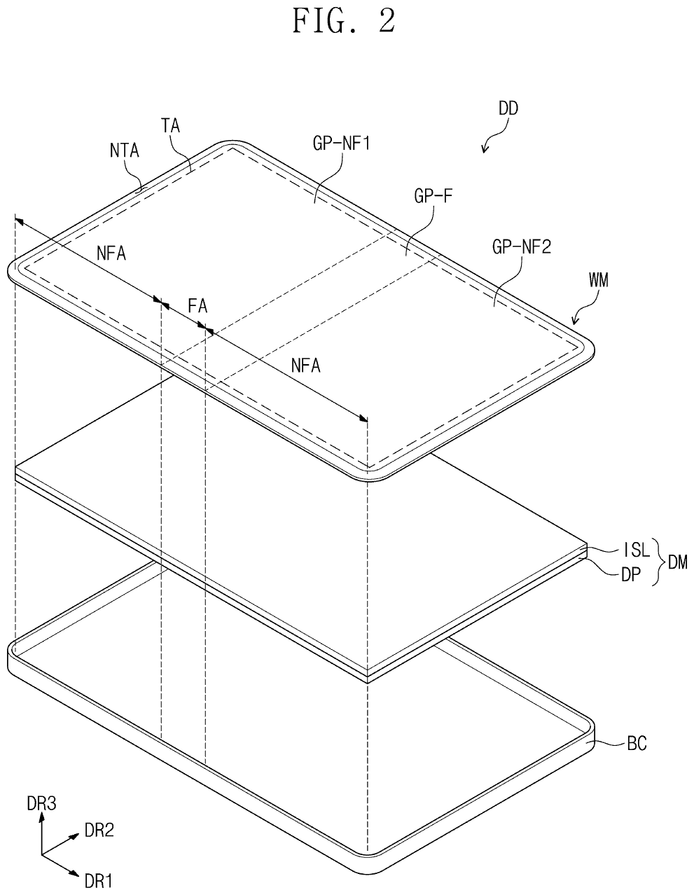

FIG. 2 is an exploded perspective view of a display device DD according to an embodiment of the invention.

Referring to FIG. 2, an embodiment of the display device DD may include a window WM, a display module DM, and an accommodating member BC.

The window WM may be disposed on the display module DM, and may transmit an image, which is provided from the display module DM, to the outside. The window WM may include a transmissive region TA and a non-transmissive region NTA. The transmissive region TA may overlap a display region DA, and may have a shape corresponding to the display region DA. An image IM displayed in the display region DA of the display device DD may be viewed from the outside through the transmissive region TA of the window WM.

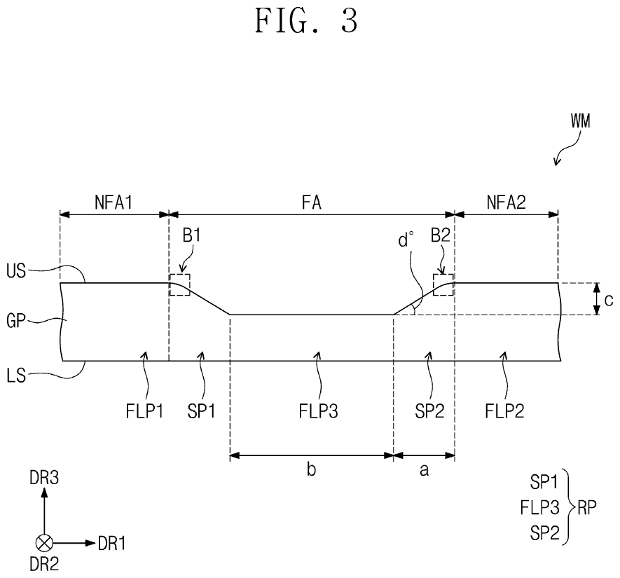

The window WM may include a glass substrate GP (see FIG. 3). The glass substrate GP (see FIG. 3) that constitutes the window WM may be an ultra-thin glass substrate having a thickness in a range of about 20 micrometers (μm) to about 100 μm. The glass substrate may have a very small thickness to be used in the flexible display device DD that is foldable or bendable. In an embodiment, for example, the glass substrate GP (see FIG. 3) may have a thickness of about 30 μm.

The non-transmissive region NTA may overlap a non-display region NDA, and have a shape corresponding to the non-display region NDA. The non-transmissive region NTA may be a region having a relatively lower light transmittance than the transmissive region TA. However, embodiments of the invention are not limited thereto, and the non-transmissive region NTA may be omitted.

In an embodiment, the window WM may include a folding portion GP-F and non-folding portions GP-NF1 and GP-NF2. The folding portion GP-F of the window WM may be a portion corresponding to the folding area FA of the display device DD. The non-folding portions GP-NF1 and GP-NF2 of the window WM may be portions corresponding to the non-folding areas NFA of the display device DD. The folding portion GP-F may be a portion that is folded when the aforementioned operation modes are performed. Accordingly, the non-folding portions GP-NF1 and GP-NF2 may be portions that are not folded when the operation modes are performed. Referring to FIG. 2, an embodiment where the non-folding portions GP-NF1 and GP-NF2 include a first non-folding portion GP-NF1 and a second non-folding portion GP-NF2, which are spaced apart from each other with the folding portion GP-F therebetween, is illustrated, but an embodiment of the invention is not limited thereto. The shapes or numbers of the folding portion GP-F and the non-folding portions GP-NF1 and GP-NF2 may be variously modified or changed to respectively correspond to the folding area FA and the non-folding areas NFA.

The display module DM may be disposed between the window WM and the accommodating member BC. The display module DM may include a display panel DP and an input sensing layer ISL disposed on the display panel DP. The display panel DP may generate an image and deliver the generated image to the window WM. According to an embodiment of the invention, the display panel DP may be a light-emitting display panel, but the type thereof is not particularly limited. In an embodiment, for example, the display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, or the like. Hereinafter, for convenience of description, embodiments where the display panel DP is the organic light-emitting display panel will be mainly described as an example.

The input sensing layer ISL may be disposed between the window WM and the display panel DP. In an embodiment, as illustrated in FIG. 2, the input sensing layer ISL may entirely overlap the transmissive region TA. However, in another embodiment of the invention, the input sensing layer ISL may overlap only a portion of the transmissive region TA, or may overlap only the non-transmissive region NTA. The input sensing layer ISL may sense an input applied from the outside. The input applied from the outside may be provided in various forms. In an embodiment, for example, an external input may include various types of external inputs such as a part of the user's body, a stylus pen, light, heat, or pressure. In addition, not only a touch by a user's body part such as a hand, but also a spatial touch (for example, hovering) of approaching or becoming adjacent to the input sensing layer may be one type of the input.

The input sensing layer ISL may sense an external input and acquire coordinate information about the external input. The input sensing layer ISL according to an embodiment of the invention may sense the external input by sensing a change in capacitance caused by an external object. That is, the input sensing layer ISL according to an embodiment may be a capacitive input sensor.

The accommodating member BC may accommodate the display module DM. Although not illustrated, the accommodating member BC may include a hinge. The hinge may be formed in a portion, overlapping the folding area FA, of the accommodating member BC. In another embodiment, the accommodating member BC may be omitted.

FIG. 3 is a cross-sectional view of a window WM according to an embodiment of the invention.

Referring to FIG. 3, an embodiment of the window WM may include a glass substrate GP. The glass substrate GP may include a first non-folding area NFA1, a second non-folding area NFA2, and a folding area FA between the first and second non-folding areas NFA1 and NFA2. The first non-folding area NFA1, the second non-folding area NFA2, and the folding area FA which are defined in the glass substrate GP may respectively correspond to the first non-folding area NFA1 (see FIG. 1), the second non-folding area NFA2 (see FIG. 1), and the folding area FA (see FIG. 1) which are defined in the display device DD (see FIG. 1).

The glass substrate GP may include a first flat portion FLP1, a second flat portion FLP2, and a recessed portion RP between the first and second flat portions FLP1 and FLP2. The first flat portion FLP1 may be a portion corresponding to the first non-folding area NFA1, the second flat portion FLP2 may be a portion corresponding to the second non-folding area NFA2, and the recessed portion RP may be a portion corresponding to the folding area FA. The recessed portion RP may be a portion depressed with respect to the first and second flat portions FLP1 and FLP2 in the thickness direction or the third direction DR3 of the glass substrate GP. That is, a thickness of the glass substrate GP in the recessed portion RP may be less than a thickness of the glass substrate GP in the first and second flat portions FLP1 and FLP2. The recessed portion RP may be formed through a later-described etching process for the glass substrate GP.

The recessed portion RP may include a first inclined portion SP1 adjacent to the first non-folding area NFA1, a second inclined portion SP2 adjacent to the second non-folding area NFA2, and a third flat portion FLP3 between the first and second inclined portions SP1 and SP2.

In the recessed portion RP, the first inclined portion SP1 may be defined as a portion from a point that begins to be depressed with respect to the first flat portion FLP1 in the thickness direction of the glass substrate GP to a point that begins to be parallel to a lower surface LS of the glass substrate GP. The second inclined portion SP2 may be defined as a portion from a point that begins to be depressed with respect to the second flat portions FLP2 in the thickness direction of the glass substrate GP to a point that begins to be parallel to the lower surface LS of the glass substrate GP. The third flat portion FLP3 may be defined as a portion in parallel to the lower surface LS of the glass substrate GP.

One portion, of the first inclined portion SP1, adjacent to a boundary between the first non-folding area NFA1 and the folding area FA may have a shape curved in the thickness direction of the glass substrate GP, and at the one portion, an upper surface US of the glass substrate GP may have a curved shape. That is, at the portion adjacent to the boundary between the first non-folding area NFA1 and the folding area FA, the upper surface US of the glass substrate GP may include a curved portion (hereinafter, referred to as a first curved portion B1). More specifically, the first curved portion B1 may have a predetermined curvature, and an imaginary center of curvature with respect to the predetermined curvature may be formed or located below the upper surface US of the glass substrate GP.

One portion, of the second inclined portion SP2, adjacent to a boundary between the second non-folding area NFA2 and the folding area FA may have a shape curved in the thickness direction of the glass substrate GP, and at the one portion, an upper surface US of the glass substrate GP may have a curved shape. That is, at the portion adjacent to the boundary between the second non-folding area NFA2 and the folding area FA, the upper surface US of the glass substrate GP may include a curved portion (hereinafter, referred to as a second curved portion B2). More specifically, the second curved portion B2 may have a predetermined curvature, and an imaginary center of curvature with respect to the predetermined curvature may be formed or located below the upper surface US of the glass substrate GP.

In a conventional glass, the glass substrate GP may be etched by forming a photoresist pattern through a photolithography process, such that the one portion, of the first inclined portion SP1, adjacent to the boundary between the first non-folding area NFA1 and the folding area FA and the one portion, of the second inclined portion SP2, adjacent to the boundary between the second non-folding area NFA2 and the folding area FA may not be formed curvedly, thereby leading to an etching defect of a stepped portion that makes a boundary line between an etched portion and a non-etched portion become clear. According to a later-described glass substrate GP etching process for manufacturing the window WM according to an embodiment of the invention, the one portion, of the first inclined portion SP1, adjacent to the boundary between the first non-folding area NFA1 and the folding area FA may be formed to be more curved than in the case where the glass substrate GP is etched through the photolithography process. Likewise, the one portion, of the second inclined portion SP2, adjacent to the boundary between the second non-folding area NFA2 and the folding area FA may be formed to be more curved.

In an embodiment of the invention, the third flat portion FLP3 of the recessed portion RP may have a length b in a range of about zero (0) mm to about 25 mm. However, the length b of the third flat portion FLP3 of the recessed portion RP is not limited thereto.

In an embodiment of the invention, an angle d of inclination formed in the glass substrate GP may be less than about 0.4°. In an embodiment, for example, an angle between the upper surface US of the glass substrate GP in the first inclined portion SP1 and the upper surface US of the glass substrate GP in the third flat portion FLP3 may be about 179.6° or greater, and an angle between the upper surface US of the glass substrate GP in the second inclined portion SP2 and the upper surface US of the glass substrate GP in the third flat portion FLP3 may be about 179.6° or greater. However, the angle of inclination formed in the glass substrate GP is not limited thereto.

In an embodiment of the invention, a slope of inclination formed in the glass substrate GP may be less than about 0.007. Here, the slope of inclination formed in the glass substrate GP may mean a value obtained by dividing an inclination depth c by an inclination width a. The inclination depth c may be a vertical distance (or distance in the third direction DR3) c between the first flat portion FLP1 and the third flat portion FLP3. However, the slope of inclination formed in the glass substrate GP is not limited thereto.

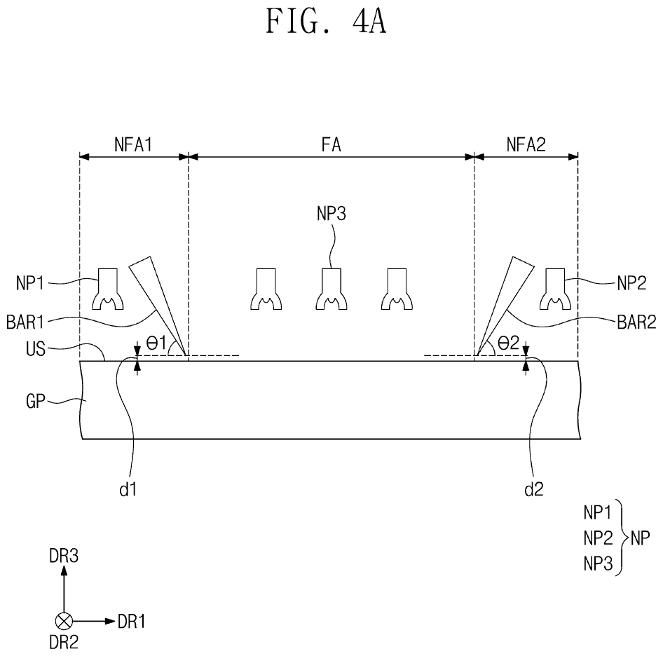

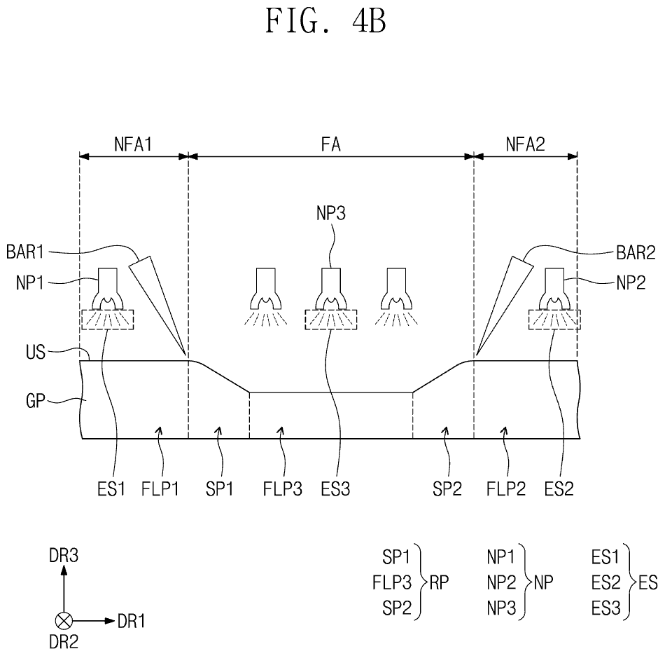

FIGS. 4A and 4B are cross-sectional views schematically illustrating processes of a method for manufacturing the window WM (see FIG. 3) according to an embodiment of the invention.

Referring to FIGS. 4A and 4B, a method for manufacturing the window WM (see FIG. 3) according to an embodiment may include a process of providing (or preparing) a glass substrate GP, a process of providing a first bar BAR1 and a second bar BAR2 on the glass substrate GP, and a process of etching the glass substrate GP. Alternatively, in this specification, the process of providing the glass substrate GP and the process of providing the first bar BAR1 and the second bar BAR2 on the glass substrate GP may be described as a process of providing the glass substrate GP under the first bar BAR1 and the second bar BAR2.

Referring to FIG. 4A, in the process of providing the glass substrate GP, the glass substrate GP may include a first non-folding area NFA1, a second non-folding area NFA2, and a folding area FA between the first and second non-folding areas NFA1 and NFA2. The first non-folding area NFA1, the second non-folding area NFA2, and the folding area FA, which are defined in the glass substrate GP, may respectively correspond to the first non-folding area NFA1 (see FIG. 1), the second non-folding area NFA2 (see FIG. 1), and the folding area FA (see FIG. 1), which are defined in the display device DD (see FIG. 1).

In the process of providing the first bar BAR1 and the second bar BAR2, the first bar BAR1 and the second bar BAR2 may be disposed on an upper surface US of the glass substrate GP. The first bar BAR1 and the second bar BAR2 may be provided to be inclined with respect to the upper surface US of the glass substrate GP, and the first bar BAR1 and the second bar BAR2 may be provided to be spaced apart from the glass substrate GP. In addition, the first bar BAR1 may overlap the first non-folding area NFA1, and the second bar BAR2 may overlap the second non-folding area NFA2. In this specification, the wording “a bar overlaps a region” may also include a meaning that at least a portion of the bar overlaps at least a portion of the region.

An imaginary line connecting one end of the first bar BAR1 adjacent to the glass substrate GP to one end of the second bar BAR2 adjacent to the glass substrate GP may be provided to be parallel to an imaginary line connecting the other end of the first bar BAR1 to the other end of the second bar BAR2. A length of the imaginary line connecting one end of the first bar BAR1 adjacent to the glass substrate GP to one end of the second bar BAR2 adjacent to the glass substrate GP may be provided to be less than a length of the imaginary line connecting the other end of the first bar BAR1 to the other end of the second bar BAR2.

The first bar BAR1 may include one end that is adjacent to the glass substrate GP, and the other end that is relatively spaced apart from the glass substrate GP and opposed to the one end. The first bar BAR1 may be disposed in a way such that as going from the other end to the one end, the first bar BAR1 is inclined in a direction from the first non-folding area NFA1 toward the folding area FA. That is, the first bar BAR1 may be disposed to be inclined so that the one end thereof gets closer to the inner of the folding area FA. The second bar BAR2 may include one end that is adjacent to the glass substrate GP, and the other end that is relatively spaced apart from the glass substrate GP and opposed to the one end. The second bar BAR2 may be disposed such that as going from the other end to the one end, the second bar BAR2 is inclined in a direction from the second non-folding area NFA2 toward the folding area FA. That is, the second bar BAR2 may be disposed to be inclined in a way such that the one end thereof gets closer to the inner of the folding area FA.

A spaced distance d1 from the first bar BAR1 to the glass substrate GP in the third direction DR3 may be provided to be the same as a spaced distance d2 from the second bar BAR2 to the glass substrate GP in the third direction DR3. More specifically, the distance d1 from the one end of the first bar BAR1 adjacent to the glass substrate GP to the upper surface US of the glass substrate GP in the third direction DR3 may be provided to be the same as the distance d2 from the one end of the second bar BAR2 adjacent to the glass substrate GP to the upper surface US of the glass substrate GP in the third direction DR3. However, the invention is not limited to any one embodiment.

An angle θ1 between the first bar BAR1 and the upper surface US of the glass substrate GP may be provided to be the same as an angle θ2 between the second bar BAR2 and the upper surface US of the glass substrate GP. More specifically, an angle (corresponding to θ1) between an imaginary line extending from the one end of the first bar BAR1 adjacent to the glass substrate GP and the upper surface US of the glass substrate GP may be provided to be the same as an angle (corresponding to θ2) between an imaginary line extending from the one end of the second bar BAR2 adjacent to the glass substrate GP and the upper surface US of the glass substrate GP. However, the invention is not limited to any one embodiment.

Referring to FIGS. 4A and 4B, in the process of etching the glass substrate GP according to an embodiment of the invention, an etching solution ES may be directly provided to the upper surface US of the glass substrate GP. Here, the etching solution ES may be provided to all or entirely over the first non-folding area NFA1, the second non-folding area NFA2, and the folding area FA. According to an embodiment, a photolithography process for patterning before the process of etching the glass substrate GP may be omitted.

In the process of etching the glass substrate GP, an etch rate of the folding area FA may be greater than an etch rate of each of the first non-folding area NFA1 and the second non-folding area NFA2. Here, the wording an “etch rate” may mean an amount etched per second in the thickness direction of the glass substrate GP. The wording an “etch rate” may mean an etching speed at room temperature (about 25° C.). A unit of the etch rate may be indicated as angstrom per second (A/s). The “etch rate” may be calculated through Equation 1 below.

Etch rate=(T1−T2)/S1 [Equation 1]

In above Equation 1, T1 denotes an initial thickness of the glass substrate GP before etching, T2 denotes a thickness of the glass substrate GP after etching, and S1 denotes a second which is the time taken to be processed with the etching solution ES.

In an embodiment, a concentration of an etching solution ES3, provided to the folding area FA, of the etching solution ES may be different from a concentration of an etching solution ES1, provided to the first non-folding area NFA1, of the etching solution ES and a concentration of an etching solution ES2, provided to the second non-folding area NFA2, of the etching solution ES. Here, the concentration may mean a proportion of a solute contained in a certain amount of a solution. The concentration of the etching solution ES3 provided to the folding area FA may be higher than the concentration of the etching solution ES1 provided to the first non-folding area NFA1 and the concentration of the etching solution ES2 provided to the second non-folding area NFA2.

In an embodiment, a temperature of the etching solution ES3 provided to the folding area FA may be different from a temperature of the etching solution ES1 provided to the first non-folding area NFA1 and a temperature of the etching solution ES2 provided to the second non-folding area NFA2. The temperature of the etching solution ES3 provided to the folding area FA may be higher than the temperature of the etching solution ES1 provided to the first non-folding area NFA1 and the temperature of the etching solution ES2 provided to the second non-folding area NFA2.

According to an embodiment, the etching solutions ES provided to the folding area FA and the non-folding areas NFA1 and NFA2 may be set to be different from each other in only one condition among the concentration and the temperature, or may be set to be different form each other in both the concentration and the temperature.

The concentration of the etching solution ES3 provided to the folding area FA is set to be higher than the concentration of the etching solution ES1 provided to the first non-folding area NFA1 and the concentration of the etching solution ES2 provided to the second non-folding area NFA2, and therefore the etch rate of the folding area FA may become higher than the etch rate of each of the first non-folding area NFA1 and the second non-folding area NFA2. Alternatively, the temperature of the etching solution ES3 provided to the folding area FA is set to be higher than the temperature of the etching solution ES1 provided to the first non-folding area NFA1 and the temperature of the etching solution ES2 provided to the second non-folding area NFA2, and therefore the etch rate of the folding area FA may become higher than the etch rate of each of the first non-folding area NFA1 and the second non-folding area NFA2. In the process of etching the glass substrate GP, the etch rate of the folding area FA is set to be higher than the etch rate of each of the first non-folding area NFA1 and the second non-folding area NFA2 and thus inclined portions and a recessed portion may be formed inside the folding area FA of the glass substrate GP.

Referring to FIG. 4B, in the process of etching the glass substrate GP according to an embodiment of the invention, a first flat portion FLP1, a second flat portion FLP2, and a recessed portion RP between the first and second flat portions FLP1 and FLP2 may be formed in the etched glass substrate GP. That is, the etched glass substrate GP may include the first flat portion FLP1, the second flat portion FLP2, and the recessed portion RP. The first flat portion FLP1 may be formed inside the first non-folding area NFA1, and the second flat portion FLP2 may be formed inside the second non-folding area NFA2. The recessed portion RP may be formed inside the folding area FA.

The recessed portion RP may include a first inclined portion SP1 adjacent to the first non-folding area NFA1, a second inclined portion SP2 adjacent to the second non-folding area NFA2, and a third flat portion FLP3 between the first and second inclined portions SP1 and SP2.

In the process of etching the glass substrate GP, the etching solution ES1 provided to the first non-folding area NFA1 may flow and move along the upper surface US of the glass substrate GP in a direction from the first non-folding area NFA1 toward the folding area FA. The etching solution ES2 provided to the second non-folding area NFA2 may flow and move along the upper surface US of the glass substrate GP in a direction from the second non-folding area NFA2 toward the folding area FA. The etching solution ES3 provided to the folding area FA may etch a portion adjacent to the boundary between the first non-folding area NFA1 and the folding area FA. In addition, the etching solution ES3 provided to the folding area FA may etch a portion adjacent to the boundary between the second non-folding area NFA2 and the folding area FA. Accordingly, one portion, of the first inclined portion SP1, adjacent to the boundary between the first non-folding area NFA1 and the folding area FA may be formed to be more curved. Likewise, one portion, of the second inclined portion SP2, adjacent to the boundary between the second non-folding area NFA2 and the folding area FA may be formed to be more curved. An inclination of the glass substrate GP inside the folding area FA may be formed to be relatively gentle.

In an embodiment, in the process of providing the first bar BAR1 and the second bar BAR2, or in the process of etching the glass substrate GP, a flow direction of the etching solution ES may be controlled by controlling at least one selected from the spaced distance d1 between the first bar BAR1 and the glass substrate GP, the spaced distance d2 between the second bar BAR2 and the glass substrate GP, the angle θ1 between the first bar BAR1 and the upper surface US of the glass substrate GP, and the angle θ2 between the second bar BAR2 and the upper surface US of the glass substrate GP. Accordingly, in such an embodiment, a degree of curve in the portion of the first inclined portion SP1 adjacent to the boundary between the first non-folding area NFA1 and the folding area FA, a degree of curve in the portion of the second inclined portion SP2 adjacent to the boundary between the second non-folding area NFA2 and the folding area FA, an angle of inclination in the folding area FA, and a depth of inclination in the folding area FA may be effectively controlled.

Referring to FIGS. 4A and 4B, the process of etching the glass substrate GP may further include a process of providing nozzle parts NP on the upper surface US of the glass substrate GP. The nozzle parts NP may be disposed on the upper surface US of the glass substrate GP.

In the process of providing the nozzle parts NP, the nozzle parts NP may include a first nozzle part NP1 disposed overlapping (to overlap) the first non-folding area NFA1, a second nozzle part NP2 disposed overlapping the second non-folding area NFA2, and a third nozzle part NP3 disposed overlapping the folding area FA. The first bar BAR1 may be disposed between the first nozzle part NP1 and the third nozzle part NP3, and the second bar BAR2 may be disposed between the second nozzle part NP2 and the third nozzle part NP3.

Referring to FIG. 4B, in the process of etching the glass substrate GP, the etching solution ES may be sprayed through the nozzle parts NP and directly provided to the upper surface US of the glass substrate GP. In an embodiment, for example, the etching solution ES1 sprayed through the first nozzle part NP1 may be directly provided to the first non-folding area NFA1 of the glass substrate GP, the etching solution ES2 sprayed through the second nozzle part NP2 may be directly provided to the second non-folding area NFA2 of the glass substate GP, and the etching solution ES3 sprayed through the third nozzle part NP3 may be directly provided to the folding area FA of the glass substrate GP.

The etching solution ES1 sprayed through the first nozzle part NP1, the etching solution ES2 sprayed through the second nozzle part NP2, and the etching solution ES3 sprayed through the third nozzle part NP3 may have concentrations different from each other. Here, the concentration means a proportion of a solute contained in a certain amount of solution.

In an embodiment, the concentration of the etching solution ES3 sprayed through the third nozzle part NP3 may be higher than the concentration of the etching solution ES1 sprayed through the first nozzle part NP1 and the concentration of the etching solution ES2 sprayed through the second nozzle part NP2.

In an embodiment, the temperature of the etching solution ES3 sprayed through the third nozzle part NP3 may be higher than the temperature of the etching solution ES1 sprayed through the first nozzle part NP1 and the temperature of the etching solution ES2 sprayed through the second nozzle part NP2. In an embodiment, for example, temperature of the third nozzle part NP3 may be set to be higher than temperatures of the first and second nozzle parts NP1 and NP2. Alternatively, a storage container for the etching solution ES3 provided to the third nozzle part NP3 may be provided at a higher temperature than storage containers for the etching solutions ES1 and ES2 provided to the first and second nozzle parts NP1 and NP2

The etching solution ES1 sprayed through the first nozzle part NP1 may flow and move along the upper surface US of the glass substate GP in the direction from the first non-folding area NFA1 toward the folding area FA. The etching solution ES2 sprayed through the second nozzle part NP2 may flow and move along the upper surface US of the glass substrate GP in the direction from the second non-folding area NFA2 toward the folding area FA. The etching solution ES3 sprayed through the third nozzle part NP3 may etch a portion adjacent to the boundary between the first non-folding area NFA1 and the folding area FA. In addition, the etching solution ES3 sprayed through the third nozzle part NP3 may etch a portion adjacent to the boundary between the second non-folding area NFA2 and the folding area FA. Accordingly, one portion, of the first inclined portion SP1, adjacent to the boundary between the first non-folding area NFA1 and the folding area FA may be formed to be more curved. Likewise, one portion, of the second inclined portion SP2, adjacent to the boundary between the second non-folding area NFA2 and the folding area FA may be formed to be more curved. The inclination of the glass substrate GP in the folding area FA may be formed to be relatively gentle.

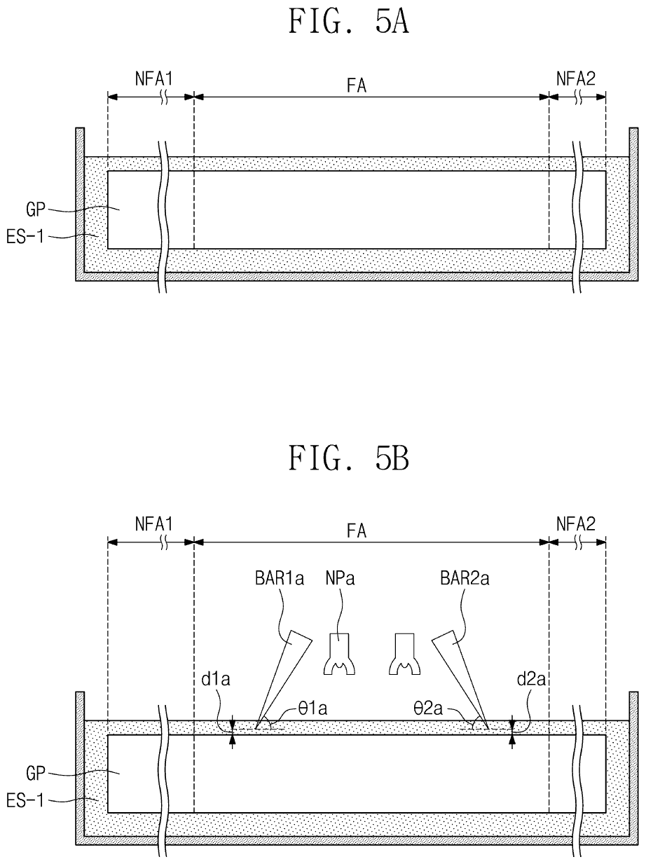

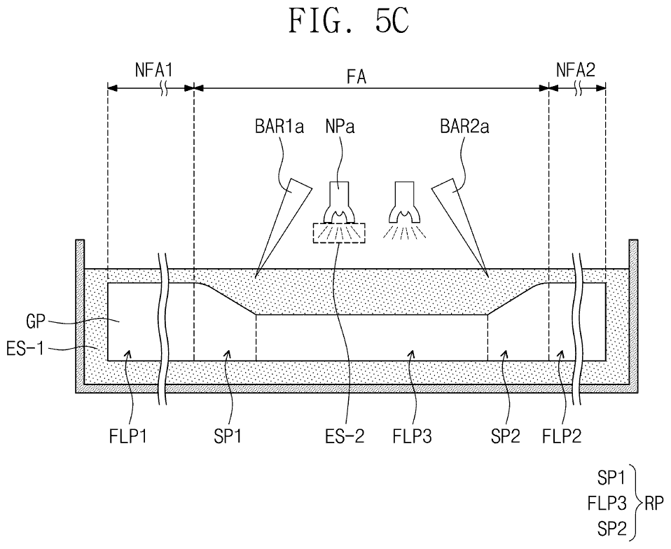

FIGS. 5A to 5C are cross-sectional views schematically illustrating processes of a method for manufacturing a window WM according to an embodiment of the invention. Hereinafter, in description made with reference to FIGS. 5A to 5C, components that are the same as/similar to the components described with reference to FIGS. 3 to 4B will be denoted as the same/similar reference numerals or symbols, and a duplicate explanation thereof will be omitted.

Referring to FIGS. 5A to 5C, a process of etching a glass substrate GP according to an embodiment may further include a process of immersing the glass substrate GP in a first etching solution ES-1, a process of providing a nozzle part NPa to overlap a folding area FA, and a process of spraying a second etching solution ES-2 onto the folding area FA through the nozzle part NPa.

Referring to FIG. 5A, in the process of immersing the glass substrate GP in the first etching solution ES-1, an entire portion of the glass substrate GP including an upper surface US of the glass substrate GP may be immersed in the first etching solution ES-1.

Referring to FIG. 5B, in an embodiment, first and second bars BAR1a and BAR2a may be provided to overlap the folding area FA.

The first bar BAR1a and the second bar BAR2a may be provided to be inclined with respect to the upper surface US of the glass substrate GP. An imaginary line connecting one end of the first bar BAR1a to one end of the second bar BAR2a may be provided to be parallel to an imaginary line connecting the other end of the first bar BAR1a to the other end of the second bar BAR2a. A length of the imaginary line connecting one end, of the first bar BAR1a, adjacent to the glass substrate GP to one end, of the second bar BAR2a, adjacent to the glass substrate GP may be provided to be longer than a length of the imaginary line connecting the other end of the first bar BAR1a to the other end of the second bar BAR2a.

The first bar BAR1a may include one end that is adjacent to the glass substrate GP and the other end that is relatively spaced apart from the glass substrate GP and opposed to the one end. The first bar BAR1a may be disposed such that as going from the other end to the one end, the first bar BAR1a is inclined in a direction from the folding area FA toward a first non-folding area NFA1. That is, the first bar BAR1a may be disposed to be inclined in a way such that the one end thereof gets closer to an inner of the first non-folding area NFA1. The second bar BAR2a may include one end that is adjacent to the glass substrate GP and the other end that is relatively spaced apart from the glass substrate GP and opposed to the one end. The second bar BAR2a may be disposed in a way such that as going from the other end to the one end, the second bar BAR2a is inclined in a direction from the folding area FA toward a second non-folding area NFA2. That is, the second bar BAR2a may be disposed to be inclined in a way such that the one end thereof gets closer to an inner of the second non-folding area NFA2.

A spaced distance d1a from the first bar BAR1a to the glass substrate GP may be provided to be the same as a spaced distance d2a from the second bar BAR2a to the glass substrate GP. More specifically, the distance d1a from one end, of the first bar BAR1a, adjacent to the glass substrate GP to the upper surface US of the glass substrate GP may be provided to be the same as the distance d2a from one end, of the second bar BAR2a, adjacent to the glass substrate GP to the upper surface US of the glass substrate GP. However, the invention is not limited to any one embodiment.

An angle θ1a between the first bar BAR1a and the upper surface US of the glass substrate GP may be provided to be the same as an angle θ2a between the second bar BAR2a and the upper surface US of the glass substrate GP. More specifically, an angle (corresponding to the angle θ1a) between an imaginary line extending from the one end, of the first bar BAR1a, adjacent to the glass substrate GP and the upper surface US of the glass substrate GP may be provided to be the same as an angle (corresponding to the angle θ2a) between an imaginary line extending from the one end, of the second bar BAR2a, adjacent to the glass substrate GP and the upper surface US of the glass substrate GP. However, the invention is not limited to any one embodiment.

Referring to FIG. 5B, in the process of providing the nozzle part NPa to overlap the folding area FA, the nozzle part NPa may be disposed between the first bar BAR1a and the second bar BAR2a. Nozzles may not be disposed on the first non-folding area NFA1 and the second non-folding area NFA2. That is, the nozzle part NPa may be disposed while overlapping only the folding area FA. The second etching solution ES-2 (see FIG. 5C) to be described later may not be sprayed onto the first non-folding area NFA1 and the second non-folding area NFA2.

Referring to FIGS. 5B and 5C, in the process of spraying the second etching solution ES-2 onto the folding area FA through the nozzle part NPa, the second etching solution ES-2 may be directly sprayed onto the folding area FA.

In an embodiment, a concentration of the first etching solution ES-1 and a concentration of the second etching solution ES-2 may be different from each other. In an embodiment, for example, the concentration of the second etching solution ES-2 may be higher than the concentration of the first etching solution ES-1.

In an embodiment, a temperature of the first etching solution ES-1 and a temperature of the second etching solution ES-2 may be different from each other. In an embodiment, for example, the temperature of the second etching solution ES-2 may be higher than the temperature of the first etching solution ES-1.

According to an embodiment, the first etching solution ES-1 and the second etching solution ES-2 may be set to be different from each other in only one condition among the concentration and the temperature, or may be set to be different from each other in both the concentration and the temperature.

By making the concentration of the second etching solution ES-2 be higher than the concentration of the first etching solution ES-1, an etch rate of the folding area FA may become higher than an etch rate of each of the first non-folding area NFA1 and the second non-folding area NFA2. Alternatively, by making the temperature of the second etching solution ES-2 be higher than the temperature of the first etching solution ES-1, the etch rate of the folding area FA may become higher than the etch rate of each of the first non-folding area NFA1 and the second non-folding area NFA2. In the process of etching the glass substrate GP, the etch rate of the folding area FA is made to be higher than the etch rate of each of the first non-folding area NFA1 and the second non-folding area NFA2, and thus inclined portions and a recessed portion may be formed in the folding area FA of the glass substrate GP.

Referring to FIG. 5C, in an embodiment of the invention, a first flat portion FLP1, a second flat portion FLP2, and a recessed portion RP between the first and second flat portions FLP1 and FLP2 may be formed in the etched glass substrate GP. That is, the etched glass substrate GP may include the first flat portion FLP1, the second flat portion FLP2, and the recessed portion RP.

The recessed portion RP may include a first inclined portion SP1 adjacent to the first non-folding area NFA1, a second inclined portion SP2 adjacent to the second non-folding area NFA2, and a third flat portion FLP3 between the first and second inclined portions SP1 and SP2.

The second etching solution ES-2 may etch a portion adjacent to a boundary between the first non-folding area NFA1 and the folding area FA. In addition, the second etching solution ES-2 may etch a portion adjacent to a boundary between the second non-folding area NFA2 and the folding area FA. Accordingly, one portion, of the first inclined portion SP1, adjacent to the boundary between the first non-folding area NFA1 and the folding area FA may be formed to be more curved. Likewise, one portion, of the second inclined portion SP2, adjacent to the boundary between the second non-folding area NFA2 and the folding area FA may be formed to be more curved. An inclination of the glass substrate GP in the folding area FA may be formed to be relatively gentle.

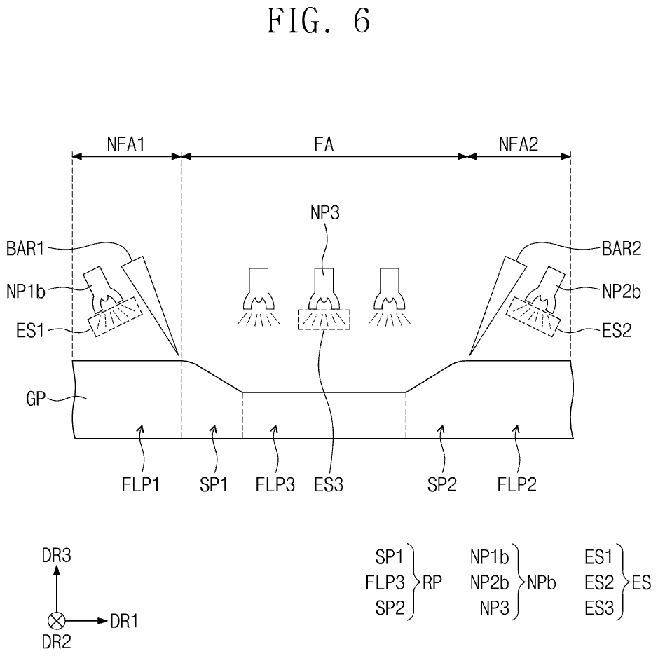

FIG. 6 is a cross-sectional view schematically illustrating a process of a method for manufacturing a window WM according to an embodiment of the invention. FIG. 6 is a cross-sectional view illustrating a process of etching a glass substrate GP according to an embodiment of the invention. Hereinafter, in description of an embodiment shown in FIG. 6, components that are the same as/similar to the components described above with reference to FIGS. 3 to 4B will be denoted as the same/similar reference numerals or symbols, and any repetitive detailed description thereof will be omitted.

Referring to FIG. 6, in an embodiment of the invention, the process of etching the glass substrate GP may further include a process of providing nozzle parts NPb on an upper surface US of the glass substrate GP. The nozzle parts NPb may include a first nozzle part NP1b disposed overlapping a first non-folding area NFA1, a second nozzle part NP2b disposed overlapping a second non-folding area NFA2, and a third nozzle part NP3 disposed overlapping a folding area FA.

In this embodiment, the first nozzle part NP1b disposed overlapping the first non-folding area NFA1 and the second nozzle part NP2b disposed overlapping the second non-folding area NFA2 may be disposed to be inclined with respect to the upper surface US of the glass substrate GP. In an embodiment, for example, the first nozzle part NP1b may be disposed to be inclined in a way such that a spraying portion thereof, from which an etching solution ES is sprayed, faces the folding area FA. The second nozzle part NP2b may be disposed to be inclined in a way such that a spraying portion thereof, from which the etching solution ES is sprayed, faces the folding area FA. In an embodiment, the first and second nozzle parts NP1b and NP2b may be respectively disposed in parallel to first and second bars BAR1 and BAR2 which are disposed to be inclined. However, an embodiment of the invention is not limited thereto, and inclined angles of the first and second nozzle parts NP1b and NP2b and inclined angles of the first and second bars BAR1 and BAR2 may be controlled independently.

In such an embodiment, a flow direction of an etching solution ES1 sprayed through the first nozzle part NP1b and a flow direction of an etching solution ES2 sprayed through the second nozzle part NP2b may be respectively controlled depending on an angle between the first nozzle part NP1b and the upper surface US of the glass substrate GP and an angle between the second nozzle part NP2b and the upper surface US of the glass substrate GP. Accordingly, in such an embodiment, a degree of curve in one portion, of a first inclined portion SP1, adjacent to a boundary between the first non-folding area NFA1 and the folding area FA, a degree of curve in one portion, of a second inclined portion SP2, adjacent to a boundary between the second non-folding area NFA2 and the folding area FA, an angle of inclination in the folding area FA, and a depth of inclination in the folding area FA may be effectively controlled.

According to embodiments of the invention, since an etching process is performed by providing an etching solution to an entire surface of a glass substrate, a boundary portion between a folding area and a non-folding area may be formed to be curved, thereby substantially reducing or effectively preventing an etching defect of a stepped portion. Accordingly, a window in which impact resistance and a defective exterior are improved may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method for manufacturing a window, the method comprising:
providing a glass substrate including a first non-folding area, a second non-folding area, and a folding area between the first and second non-folding areas;
providing, on the glass substrate, a first bar and a second bar, each of which is inclined with respect to an upper surface of the glass substrate, and spaced apart from the glass substrate; and
etching the glass substrate by providing an etching solution to the upper surface of the glass substrate,
wherein in the etching the glass substrate, a recessed portion is formed in the folding area.

2. The method of claim 1, wherein the recessed portion comprises a first inclined portion adjacent to the first non-folding area, a second inclined portion adjacent to the second non-folding area, and a third flat portion between the first and second inclined portions, and
in the etching the glass substrate, a portion, of the first inclined portion, adjacent to a boundary between the first non-folding area and the folding area, and a portion, of the second inclined portion, adjacent to a boundary between the second non-folding area and the folding area each are formed to be curved.

3. The method of claim 1, wherein the etching solution is directly provided to the glass substrate.

4. The method of claim 1, wherein in the etching the glass substrate, the etching solution provided to the first non-folding area flows and moves along the upper surface of the glass substrate in a direction from the first non-folding area toward the folding area, and the etching solution provided to the second non-folding area flows and moves along the upper surface of glass substrate in a direction from the second non-folding area toward the folding area.

5. The method of claim 1, wherein in the etching the glass substrate, an etch rate of the folding area is greater than an etch rate of each of the first non-folding area and the second non-folding area.

6. The method of claim 1, wherein the etching the glass substrate comprises:
providing a nozzle part to overlap the folding area, the first non-folding area, and the second non-folding area; and
spraying the etching solution onto the glass substrate through the nozzle part.

7. The method of claim 6, wherein in the providing the first bar and the second bar, the first bar and the second bar overlap the first non-folding area and the second non-folding area, respectively,
the first bar is disposed to be inclined in a way such that one end of the first bar, which is adjacent to the glass substrate, gets closer to an inner of the folding area, and
the second bar is disposed to be inclined in a way such that one end of the second bar, which is adjacent to the glass substrate, gets closer to an inner side of the folding area.

8. The method of claim 6, wherein
the etching solution, which is provided to the first non-folding area through the nozzle part, flows and moves along the upper surface of the glass substrate in a direction from the first non-folding area toward the folding area, and
the etching solution, which is provided to the second non-folding area through the nozzle part, flows and moves along the upper surface of the glass substrate in a direction from the second non-folding area toward the folding area.

9. The method of claim 6, wherein the nozzle part comprises:
a first nozzle part disposed overlapping the first non-folding area;
a second nozzle part disposed overlapping the second non-folding area; and
a third nozzle part disposed overlapping the folding area, and
a concentration of the etching solution sprayed from the third nozzle part is higher than a concentration of the etching solution sprayed from the first nozzle part and a concentration of the etching solution sprayed from the second nozzle part.

10. The method of claim 6, wherein the nozzle part comprises:
a first nozzle part disposed overlapping the first non-folding area;
a second nozzle part disposed overlapping the second non-folding area; and
a third nozzle part disposed overlapping the folding area, and
a temperature of the etching solution sprayed from the third nozzle part is higher than a temperature of the etching solution sprayed from the first nozzle part and a temperature of the etching solution sprayed from the second nozzle part.

11. The method of claim 6, wherein the nozzle part comprises:
a first nozzle part disposed overlapping the first non-folding area;
a second nozzle part disposed overlapping the second non-folding area; and
a third nozzle part disposed overlapping the folding area, and
a flow direction of the etching solution is adjusted by controlling an angle of each of the first nozzle part and the second nozzle part.

12. The method of claim 1, wherein the etching the glass substrate comprises:
immersing the glass substrate in a first etching solution;
providing a nozzle part to overlap the folding area; and
spraying a second etching solution onto the folding area through the nozzle part.

13. The method of claim 12, wherein in the providing the first bar and the second bar, each of the first bar and the second bar overlaps the folding area of the glass substrate,
the first bar is disposed to be inclined in a way such that one end of the first bar adjacent to the glass substrate gets closer to an inner of the first non-folding area, and
the second bar is disposed to be inclined in a way such that one end of the second bar adjacent to the glass substrate gets closer to an inner of the second non-folding area.

14. The method of claim 12, wherein the nozzle part is not provided to the first non-folding area and the second non-folding area of the glass substrate, and the second etching solution is not sprayed thereto.

15. The method of claim 12, wherein a concentration of the second etching solution sprayed onto the folding area is higher than a concentration of the first etching solution.

16. The method of claim 1, wherein in the providing the first bar and the second bar, a spaced distance from the first bar to the glass substrate is the same as a spaced distance from the second bar to the glass substrate, and
an angle between the first bar and the upper surface of the glass substrate is the same as an angle between the second bar and the upper surface of the glass substrate.

17. A method for manufacturing a window, the method comprising:
providing a glass substrate under a first bar and a second bar; and
etching the glass substrate by providing an etching solution to an entire upper surface of the glass substrate,
wherein in the providing the glass substrate, each of the first bar and the second bar is inclined with respect to the upper surface of the glass substrate, and
in the etching the glass substrate, a first flat portion, a second flat portion, and a recessed portion between the first and second flat portions are formed in the glass substrate.

18. The method of claim 17, wherein the recessed portion comprises a first inclined portion adjacent to a first non-folding area, a second inclined portion adjacent to a second non-folding area, and a third flat portion between the first and second inclined portions, and
in the etching of the glass substrate, a portion, of the first inclined portion, adjacent to a boundary between the first non-folding area and a folding area and a portion, of the second inclined portion, adjacent to a boundary between the second non-folding area and the folding area are each formed to be curved.

19. The method of claim 18, wherein a flow direction of the etching solution is controlled by controlling at least one selected from a spaced distance between the first bar and the glass substrate, a spaced distance between the second bar and the glass substrate, an angle between the first bar and the upper surface of the glass substrate, and an angle between the second bar and the upper surface of the glass substrate.

20. An electronic device comprising:
a window manufactured by a method comprising:
providing a glass substrate including a first non-folding area, a second non-folding area, and a folding area between the first and second non-folding areas;
providing, on the glass substrate, a first bar and a second bar each of which is inclined with respect to an upper surface of the glass substrate, and spaced apart from the glass substrate; and
etching the glass substrate by providing an etching solution to the upper surface of the glass substrate,
wherein in the etching the glass substrate, a recessed portion is formed in the folding area.
